(19) United States
(12) Patent Application Publication
(10) Pub. No.: US 2024/0106184 A1
(43) Pub. Date: Mar. 28, 2024

(54) LASER OSCILLATOR SYSTEM AND METHOD FOR GENERATING LIGHT PULSES

(71) Applicants: Max-Planck-Gesellschaft zur Förderung der Wissenschaften e.V., München (DE); Ludwig-Maximilians-Universität München, München (DE)

(72) Inventors: Ka Fai Mak, München (DE); Ferenc Krausz, Garching (DE); Philipp Steinleitner, München (DE); Nathalie Lenke, München (DE)

(21) Appl. No.: 18/527,819

(22) Filed: Dec. 4, 2023

Related U.S. Application Data
(63) Continuation of application No. PCT/EP22/65388, filed on Jun. 7, 2022.

(30) Foreign Application Priority Data
Jun. 8, 2021 (WO) PCT/EP2021/065370

(51) Int. Cl. H01S 3/0941; H01S 3/00; H01S 3/08; H01S 5/14

(52) U.S. Cl. CPC H01S 3/09415; H01S 3/0057; H01S 3/08059; H01S 5/142

(57) ABSTRACT

A laser oscillator system includes a resonator cavity for confining an intra-cavity laser beam. The laser oscillator system further includes a Cr-doped II-VI gain medium arranged within the resonator cavity and an imaging unit forming part of the resonator cavity. The imaging unit is configured to decouple a spot size of the intra-cavity laser beam at the gain medium from an intra-cavity length of the resonator cavity. Moreover, the resonator cavity and the imaging unit are configured such that the laser oscillator system emits laser pulses at a repetition rate of 50 MHz or less. Further, a laser system and methods for generating light pulses having spectral components at a wavelength of at least 2 μm are disclosed.

### CROSS REFERENCE TO RELATED APPLICATIONS

This application is a continuation application of international patent application PCT/EP2022/065388, filed on Jun. 7, 2022, designating the United States and claiming priority from international patent application PCT/EP2021/065370, filed Jun. 8, 2021, and the entire content of both applications is incorporated herein by reference.

### TECHNICAL FIELD

Exemplary embodiments of the disclosure relate to a laser oscillator system, a laser system, a method for generating light pulses having spectral components at a wavelength of at least 2 μm, a use of a laser oscillator system for generating laser pulses having a peak power of at least 0.75 MW at a repetition rate of 50 MHz or less, and a use of rutile TiO₂ for nonlinear spectral broadening of laser pulses. The exemplary embodiments are, thus, related to laser technology.

### BACKGROUND

Femtosecond light sources in the mid-infrared (MIR) spectral range having a high brilliance and a high-photon-flux are sought after for various applications, such as spectroscopic applications both in the frequency domain and in the time domain The MIR spectral range is of particular interest, since many molecules, in particular biomolecules, exhibit characteristic spectral absorption signatures in this spectral range. Moreover, an investigation and exploitation of nonlinear optical processes would benefit from such MIR laser pulses having femtosecond pulse durations, while offering low amplitude fluctuations and timing fluctuations (noise) of the generated pulses in order to achieve a high level of measurement sensitivity.

For such applications, few-cycle pulses having a peak power on the order of 0.75 MW or higher could, via nonlinear frequency conversion, extend the spectral coverage to the MIR as well as to the ultraviolet spectral range (see S. Vasilyev et al. Octave-spanning Cr:ZnS femtosecond laser with intrinsic nonlinear interferometry, Optica 6, 126-127 (2019)). Such light pulses—if available at multi-MHz repetition rates—would enable the exploration of a plethora of new applications in molecular as well as nano-science.

Directly diode-pumped mode-locked laser oscillator systems are commonly used for the generation of femtosecond laser pulses. Compared to mode-locked lasers pumped by other solid-state (e.g., fiber) lasers, directly diode-pumped ultrashort-pulse laser oscillators are especially suited to efficiently generate few-cycle pulses exhibiting a low degree of intensity noise, as for instance described in U.S. Pat. No. 8,976,821 B2, N. Nagl, et al., “Directly diode-pumped, Ken-lens mode-locked, few-cycle Cr:ZnSe oscillator,” Opt. Express 27, 24445 (2019), and N. Nagl, et al., “Directly diode-pumped few-optical-cycle Cr:ZnS laser at 800 mW of average power,” CLEO, paper SF3H.5 (2020).

However, such systems barely reach peak power levels in excess of 100 kW which renders them insufficient to exploit optical nonlinearities for effective frequency conversion or other applications. MW-level peak powers at multi-MHz repetition rates can be achieved only by externally amplifying full pulse trains emitted by such oscillators in external laser amplifiers. External amplification has the drawback that it typically adds noise, which, thus, reduces the achievable measurement sensitivity.

Long et al.: “Third-order optical nonlinearities in anatase and rutile TIO2 thin films,” THIN SOLID FILMS, ELSEVIER, AMSTERDAM, NL, vol. 517, no. 19, 3 Aug. 2009 (2009-08-03), pages 5601-5604 describes a use of 300 nm thin rutile films with a Ti:Sapphire laser at a wavelength of 800 nm, where rutile has a nonlinear refractive index of 2.7×10⁻¹⁷ m²/W.

Koichi et al.: “Nonlinear optical waveguides with rutile TiO₂,” OXIDE-BASED MATERIALS AND DEVICES II, SPIE, 1000 20TH ST. BELLINGHAM WA 98225-6705 USA, vol. 7940, no. 1, 10 Feb. 2011 (2011-02-10), pages 1-7 describes a use of rutile TiO₂ for the fabrication of waveguides that are pumped by a Ti:Sapphire laser at a wavelength of about 800 nm.

Manon et al.: “Titanium Dioxide Waveguides for Supercontinuum Generation and Optical Transmissions in the Near- and Mid-Infrared,” 2019 21ST INTERNATIONAL CONFERENCE ON TRANSPARENT OPTICAL NETWORKS (ICTON), IEEE, 9 Jul. 2019 (2019-07-09), pages 1-4 describes the use of TiO₂ for the fabrication of waveguides that are pumped at a wavelength of 1,550 nm.

### SUMMARY

It is an object of the disclosure to generate femtosecond light pulses in the mid-infrared spectral range having a peak power of at least several 100 kW at high repetition rates and at low technical complexity and manufacturing costs. It is further desirable to provide solutions for achieving efficient spectral broadening for generating few-cycle light pulses in the MIR range at low technical complexity and at low manufacturing costs.

This objective is achieved by a laser oscillator system having a resonator cavity for confining an intra-cavity laser beam, a Cr-doped II-VI gain medium arranged within the resonator cavity; and an imaging unit forming part of the resonator cavity. Exemplary embodiments are discussed in detail below.

One exemplary embodiment relates to a laser oscillator system comprising a resonator cavity for confining an intra-cavity laser beam and a Cr-doped II-VI gain medium arranged within the resonator cavity. The laser oscillator system further comprises an imaging unit forming part of the resonator cavity, wherein the imaging unit is adapted to decouple a spot size of the intra-cavity laser beam at the gain medium from an intra-cavity length of the resonator cavity. The resonator cavity and the imaging unit are adapted such that the laser oscillator system emits laser pulses at a repetition rate of 50 MHz or less.

Another exemplary embodiment relates to a laser system, comprising a laser oscillator system according to an exemplary embodiment, wherein the laser oscillator system is adapted to emit laser pulses having a peak power of at least 0.75 MW. The laser system further comprises a nonlinear optical element having a thickness of 1 mm or less, wherein the laser system is adapted to irradiate the nonlinear optical element with the laser pulses emitted by the laser oscillator system to spectrally broaden the laser pulses such that the spectrally broadened laser pulses span at least half an optical octave.

Yet another exemplary embodiment relates to a method for generating light pulses having spectral components at a wavelength of at least 2 μm. The method comprises providing laser pulses emitted by a laser oscillator having a pulse duration of 30 fs FWHM or less, a peak power of at least 0.75 MW and a central wavelength of 1.8 μm or longer. The method further comprises focusing the laser pulses onto a nonlinear optical element having a thickness of 1 mm or less and a nonlinear refractive index n₂ of at least 5·10⁻¹⁹ m²/W at a wavelength of 2 μm.

Yet another exemplary embodiment relates to a use of a laser oscillator system according to an exemplary embodiment for generating laser pulses having a peak power of at least 0.75 MW at a repetition rate of 50 MHz or less.

Yet another exemplary embodiment relates to a use of bulk rutile TiO₂ for nonlinear spectral broadening of laser pulses having spectral components at wavelength of at least 1 μm and optionally of at least 2 μm. The spectral components may be in a wavelength range from 1 μm to 4 μm and optionally in the range from 2 μm to 3 μm.

A laser oscillator system is a laser oscillator providing laser activity within a gain medium in a resonator cavity. The laser oscillator system does not comprise any external amplification of the laser pulses after out-coupling from the resonator cavity. The laser oscillator system may comprise external pumping means, such as a pump laser, wherein the pump laser may be a part of the laser oscillator system or may be provided separately from the laser oscillator system. For instance, the laser oscillator system may be directly diode-pumped by radiation provided by light emitting diodes and/or laser diodes.

The intra-cavity laser beam is a laser beam confined within the resonator cavity. The intra-cavity laser beam is maintained within the laser cavity for multiple roundtrips, wherein a small portion of the intra-cavity may be coupled out by one of the resonator minors of the resonator cavity.

The Cr-doped II-VI gain medium comprises a II-VI bulk medium doped with chromium atoms. The II-VI medium is composed of chemical elements of the 2^{nd} main group and the 6^{th} main group according to the periodic table. The II-VI medium may comprise a II-VI crystal doped with chromium. In particular the II-VI material may comprise ZnS and/or ZnSe. However, according to other exemplary embodiments different II-VI materials may be used. Cr-doped II-VI gain media provide suitable characteristics for the generation of femtosecond laser pulses in the MIR spectral range. However, alternatively or additionally one or more other gain media may be used, as long as they are suitable for the generation of laser pulses in the MIR spectral range spectrally supporting a femtosecond pulse duration.

An imaging unit is an optical configuration for extending the length of the resonator cavity (also referred to as intra-cavity length) and by this reducing the repetition rate of the laser pulses emitted by the laser oscillator system. The imaging unit may be adapted to image the intra-cavity laser beam such as to maintain at least to some degree a transversal mode and/or a beam profile of the intra-cavity laser beam. The imaging unit may comprise transmissive optical elements, such as one or more optical lenses, and/or reflective optical elements, such as flat and/or curved mirrors. The imaging unit may be integrated into the resonator cavity. In some exemplary embodiments, the imaging unit may comprise at least one of the end mirrors of the resonator cavity.

The laser oscillator system emitting laser pulses at a repetition rate of 50 MHz or less means that the laser oscillator system is operated in a pulsed mode, for instance in a mode-locked operation, wherein the frequency, at which the laser pulses are emitted from the laser oscillator system is 50 MHz or less. Accordingly, a time distance between two consecutively emitted laser pulses is about 20 ns or more.

The laser system comprising a laser oscillator system may comprise in addition further means for altering the emitted laser pulses. For instance, the laser system may comprise further means for spectrally broadening the laser pulses. The laser system may further comprise a laser amplifier and/or an optical parametric amplifier for further amplifying the laser pulses emitted by the laser oscillator system.

The peak power of the laser pulses is the power achieved by a laser pulse at a point in time when the laser pulse has its maximum electric field strength. In other words, the peak power is the maximum power of the laser pulses. The laser pulses having a peak power of 0.75 MW or more means that the laser pulses have an electrical field strength at the maximum of the electric field in the time domain corresponding to a power of 0.75 MW.

The nonlinear optical element having a thickness of 1 mm or less means that the nonlinear optical element in the direction parallel to a propagation direction of incident laser pulses has a spatial extension of 1 mm or less.

The spectrally broadened laser pulses spanning at least half an octave means the laser pulses cover a range in the frequency domain extending from a specific first frequency to a second frequency having at least 1.5 times the frequency of the first frequency. The threshold power until which a spectral range extends is the respective wavelength or frequency, at which the spectral power distribution is attenuated by 30 dB compared to the wavelength or frequency having the maximum power.

The laser pulse durations are indicated using the commonly used parameter FWHM, which means full width at half maximum.

The use of rutile TiO₂ means that a bulk TiO₂ medium having the rutile crystal structure is used. Using TiO₂ without any explicitly specified crystal structure may comprise the use of TiO₂ in any existing crystal structure, such as anatase, brookite and rutile. However, in exemplary embodiments specifying rutile TiO₂, only the rutile crystal structure of TiO₂ is used for the respective purpose. The use of rutile TiO₂ may comprise or consist of using bulk rutile TiO₂. “Bulk” in this sense means that a bulk piece of rutile TiO₂ is used as a nonlinear optical element instead of using a waveguide structure comprising or consisting of rutile TiO₂.

Some exemplary embodiments provide the advantage that they allow generating high-peak power few-cycle laser pulses in the mid-infrared spectral range directly from a laser oscillator system. In other words, some exemplary embodiments provide the advantage that high-peak power few-cycle laser pulses in the mid-infrared spectral range may be generated without the further need of an additional external laser amplifier system in addition to the laser oscillator system. The generation of such high-peak power laser pulses directly from an oscillator system allows realizing a compact system, which may facilitate the integration of such a laser pulse source in various other systems, such as spectroscopic devices and/or security devices and/or medical devices and/or machining tools.

In addition, some exemplary embodiments provide the benefit that the technical complexity of such a laser oscillator system can be kept at a significantly lower level than conventional laser systems including a laser amplifier system. Moreover, some exemplary embodiments provide the advantage that the laser pulse source may be provided with lower manufacturing costs as compared to conventional laser pulse sources including a laser amplifier system.

The advantages are favored by increasing the intra-cavity length of the resonator cavity and consequently by reducing the repetition rate of the laser pulses emitted by the laser oscillator system. This allows achieving higher pulse energies for the individual pulses and accordingly higher peak powers than in laser oscillators systems having a higher repetition rate.

This advantage and the realization of the exemplary embodiments was understood by the inventors although it was conventionally believed in the field that achieving high peak powers in laser oscillator systems using Cr-doped II-VI gain media would result in technical disadvantages or problems occurring due to a high nonlinear refractive index. For instance, ZnSe has a nonlinear refractive index n₂ of about 1·10⁻¹⁴ cm²/W at a wavelength of 2.3 μm. Due to the high nonlinear refractive index, spatial and temporal parasitic effects and, hence, instabilities in Kerr-lens mode-locking were expected to set in already at low power levels in Cr:ZnS and Cr:ZnSe laser gain media, as compared to Ti:sapphire laser gain media with comparable oscillator parameters.

Accordingly, it was conventionally seen as obstacles for Cr-doped II-VI lasers (i) that a longer intra-cavity length of the resonator leads to a smaller spot size of the intra-cavity laser beam at the gain medium, which increases the intensity, and (ii) that a longer intra-cavity length results in a higher peak power due to a lower repetition rate, which further increases the intensity. These obstacles were conventionally believed as hindrance for the generation of high peak power laser pulses from a Cr-doped II-VI laser oscillator due to the high nonlinear refractive index. It is, thus, surprising that the inventors found that using an imaging unit for extending the intra-cavity length of the Cr-doped II-VI laser oscillator system allows increasing the intra-cavity length and accordingly reducing the repetition rate while avoiding the assumed obstacles conventionally believed to originate in the high nonlinear refractive index. The combination of the Cr-doped II-VI gain medium with the imaging unit allows decoupling the spot size of the intra-cavity length and, thus, allows reducing the repetition rate without significantly reducing the spot size of the intra-cavity laser beam at the gain medium. Accordingly, even for an intra-cavity length increased by the imaging unit and the resulting higher peak powers of the laser pulses, nonlinear effects in the gain medium and related obstacles can be avoided or reduced to an acceptable level and a laser oscillator system based on a Cr-doped II-VI gain medium can be realized for generating laser pulses having a peak power of 0.75 MW or more.

Using bulk rutile TiO₂ allows achieving supercontinuum-like spectral broadening in a bulk medium, which regularly requires a balanced interplay between self-focusing, self-phase modulation, material dispersion, and plasma generation induced by multi-photon absorption. In particular, using bulk rutile TiO₂ allows achieving the spectral broadening of laser pulses in a wavelength range from 2 μm to 3 μm and optionally from 1 μm to 4 μm in bulk medium and, thus, without the need of providing a waveguide structure confining the laser pulses at a small radius over long propagation distances. Instead, the bulk material itself defines the dispersion for spectral broadening. According to the disclosure, a spectral broadening in bulk rutile TiO₂ is achieved at an interaction length of 1 mm or less while maintaining a high quality of the beam profile facilitating the use of the laser pulses after spectral broadening. Maintaining a good beam profile may be advantageous for focusing the laser pulses after the spectral broadening. Efficient broadening of laser pulses at wavelength from 1 μm to 4 μm, and in particular from 2 μm to 3 μm, with nJ pulse energies in bulk material has strong requirements on the material properties, such as optimum group-delay and higher-order dispersion, high damage threshold and a high bandgap.

As the inventors found, rutile TiO₂ not only provides strong spectral broadening, but also long-time stability, which some other materials may lack. Even for materials with similar dispersion characteristics the inventors found substantial differences in their broadening behavior and found that rutile TiO₂ offers very beneficial spectral broadening performance in the spectral range from 1 μm to 4 μm and in particular from 2 μm to 3 μm.

Rutile's unique combination of a high nonlinear refractive index, a large optical band gap, and a zero-crossing of its optical dispersion around 2.3 μm allows generating spectral supercontinua with laser pulses at nJ-level pulse energies with Cr-doped II-VI lasers without strong residual multi-photon absorption. Moreover, the use of thin rutile plates, having a thickness of 1 mm or less, allows preserving close-to-Gaussian beam profiles, indicating high spatial quality of the laser beams. However, the thin rutile plate may have a minimum thickness of at least one hundred microns, which provides a sufficient thickness for the nonlinearity to accumulate and in return to give rise to spectral broadening. Thinner layers of only few hundred nanometers of rutile would not lead to substantial spectral broadening when used in combination with Cr-doped II-VI laser oscillator systems.

In case the properties of the beam profile after spectral broadening are not of essential importance for the intended application of the laser pulses, thicker bulk rutile TiO₂ may be used, such as having a thickness between 1 mm and 5 mm, providing a larger nonlinear interaction and, hence, a higher spectral broadening. However, keeping the thickness of the bulk rutile TiO₂ at 1 mm or less allows achieving suitable spectral broadening combined with maintaining a good quality of the beam profile.

In some exemplary embodiments the imaging unit is adapted to provide a tunable intra-cavity length. The intra-cavity length may be tunable in a predetermined range. For instance, the imaging unit may comprise one or more telescopes and tuning the intra-cavity length may include moving at least one or several of the minors and/or lenses comprised by the one or more telescopes. The imaging unit may allow to continuously tune the cavity length and/or to tune the cavity length by predetermined step sizes. Tuning the intra-cavity length may be carried out such that the laser oscillator system still allows a mode-locked operation. In particular, tuning the intra-cavity length may be carried out such that the spot-size of the intra-cavity laser beam remains unchanged for the changed intra-cavity lengths due to tuning. According to other exemplary embodiments the spot size of the intra-cavity laser beam at the gain medium may slightly vary in response to tuning the intra-cavity length of the resonator cavity. For instance, the spot size of the intra-cavity laser beam may vary by about 10% when changing the intra-cavity length by about 10%. Tuning the intra-cavity length of the resonator cavity may be carried out without the need of replacing and/or modifying one or more optical elements of the resonator cavity and/or of the imaging unit. According to other exemplary embodiments, tuning the intra-cavity length may require replacing and/or modifying one or more of the optical elements of the imaging unit and/or the resonator. Tunability of the intra-cavity length may provide the advantage of tuning the repetition rate of the laser oscillator system in a corresponding range. Thus, tuning the intra-cavity length may provide the ability of adjusting the repetition rate of the laser oscillator system for the desired application.

In some exemplary embodiments the spot size of the intra-cavity laser beam at the gain medium is adjustable. This allows adjusting the intensity of the intra-cavity laser beam at the gain medium and, thus, the gain and/or the occurrence or avoidance of effects originating from the nonlinear refractive index of the gain medium. For instance, the resonator cavity may comprise additional focusing elements for focusing the intra-cavity laser beam onto the gain medium. Adjusting these additional focusing elements may allow adjusting the spot size at the gain medium.

In some exemplary embodiments the imaging unit comprises one or more telescopes for imaging the intra-cavity laser beam, wherein the one or more telescopes optionally comprise one or more 4f-telescopes. This allows maintaining the transversal mode of the resonator cavity and in particular the beam diameter of the intra-cavity laser beam in the parts of the resonator cavity outside the imaging unit. Moreover, this allows maintaining the spot size of the intra-cavity laser beam at the gain medium and facilitates the decoupling of the intra-cavity length from the spot size at the gain medium. In some exemplary embodiments an end mirror of the resonator cavity is arranged in one of the imaging planes of the one or more telescopes. This may further facilitate maintaining a proper resonator mode for the intra-cavity laser beam.

In some exemplary embodiments the resonator cavity and optionally the imaging unit comprise one or more multipass-cells, wherein the one or more multipass-cells optionally comprise one or more Herriott-type cells. In other words, the imaging unit may include a multipass-cell for increasing the intra-cavity length of the resonator. Multipass cells may be based on reflective optical elements, such as plain and/or curved mirrors. This may bear the advantage that the dispersion within the resonator cavity can be kept low. Moreover, this may bear the advantage that a damage threshold may be achieved. Using an imaging unit comprising a multipass-cell may facilitate increasing the intra-cavity resonator length. Alternatively, or additionally the resonator cavity may comprise a multipass-cell to achieve multiple passes of the intra-cavity laser beam through the gain medium during each half round trip in the oscillator cavity. This may allow further reducing the repetition rate and increasing the laser gain per round trip.

In some exemplary embodiments the Cr-doped II-VI gain medium comprises or consists of ZnS and/or ZnSe. The II-VI gain medium may be provided as polycrystalline ZnSe and/or ZnS. Cr-doped ZnS and Cr-doped ZnSe gain media are favorable due to their widespread use as laser gain media and their abundant availability in suitable quality. In some exemplary embodiments the gain medium is oriented at a Brewster angle at the central wavelength of the intra-cavity laser beam or at a normal incidence angle of the intra-cavity laser beam when the gain medium is optionally coated with an anti-reflection coating. This may reduce losses due to undesired reflections of the intra-cavity laser beam off the gain medium.

In some exemplary embodiments the resonator cavity and the imaging unit are adapted such that the laser oscillator system emits laser pulses at a repetition rate of 40 MHz or less, optionally at a repetition rate of 30 MHz or less, optionally 20 MHz or less and optionally 10 MHz or less. This allows further increasing the pulse energy and, thus, the achievable peak power of the emitted laser pulses.

In some exemplary embodiments the laser oscillator system is adapted to emit the laser pulses having a pulse duration of 30 fs FWHM or less. The emitted laser pulses may have a peak power of at least 0.75 MW and optionally of at least 1 MW. These laser pulses may be well suited for a large variety of nonlinear optical applications, such as spectral broadening and/or for time-resolved spectroscopic applications.

In some exemplary embodiments the emitted laser pulses cover a spectral range from at least 2.0 μm to 2.8 μm. The wavelengths at which the spectral intensity distribution is attenuated by 30 dB compared to the maximum of the spectral power distribution, i.e. where the spectral intensity is 1.000 times lower than the maximum, is regarded as the cutoff wavelength until which the spectrum extends. A spectrum extending from 2.0 μm to 2.8 μm supports the generation of 30 fs pulses.

In some exemplary embodiments the laser oscillator system is adapted as a Kerr-lens mode-locked laser oscillator system. This allows an efficient generation of femtosecond laser pulses from the laser oscillator system. In some exemplary embodiments the gain medium is adapted to provide the functionality of a Kerr medium for Kerr-lens mode locking. In other words, the gain medium may provide the functionality of a laser medium and further the functionality of a Kerr-medium. Alternatively, the laser oscillator system may comprise a Kerr medium, wherein the Kerr medium is provided separately from the gain medium. This allows separating the laser activity and the Ken-lens mode locking, since the spot size of the intra-cavity laser beam at the gain medium may be adjusted independently from the spot size at the Ken-medium.

In some exemplary embodiments the Cr-doped II-VI gain medium is directly diode-pumped. The gain medium may be directly diode-pumped with optical radiation provided by light emitting diodes and/or diode lasers. Direct diode-pumping provides the advantage that a lower amplitude noise may be achieved compared to other pumping techniques and, thus, a more stable laser output may be provided which may result in a higher measurement sensitivity for applications based on the laser pulses. Moreover, directly diode-pumped laser oscillator systems may be realized in a more compact manner than laser oscillator systems pumped by fiber lasers. In addition, laser diodes for directly pumping the laser oscillator often may be provided at lower manufacturing costs than fiber lasers and therefore may enable their use in cost sensitive applications. Furthermore, directly diode-pumped laser oscillators may have higher wall-plug efficiencies and therefore may reduce the electrical power consumption.

In some exemplary embodiments the laser system is adapted to focus the laser pulses onto the nonlinear optical element. This allows achieving high intensities within the nonlinear optical element and, thus, an efficient exploitation of the nonlinear optical effects occurring in the nonlinear optical element. In particular, focusing the laser pulses onto the nonlinear optical element may allow reducing the thickness of the nonlinear optical element while still achieving the desired nonlinear optical effect, which may be beneficial for maintaining a beam profile having a high quality, such as having a low beam quality factor M², optionally a beam quality factor close to 1.2.

In some exemplary embodiments the laser system is adapted such that the spectrum of the laser pulses can support a pulse duration of 15 fs FWHM or less after propagating through the nonlinear optical element. In other words, the spectrum may be adapted after spectral broadening in the nonlinear optical element such that the Fourier transform of the spectral power distribution corresponds to a temporal power distribution of a laser pulse having a pulse duration of 15 fs or less. For providing laser pulses having a pulse duration of 15 fs or less, controlling the dispersion may be advantageous. A pulse compression of the laser pulses after the nonlinear optical element and/or before the nonlinear optical element for a pre-compensation of dispersion may be applied for providing laser pulses having a pulse duration of 15 fs or less.

In some exemplary embodiments the nonlinear optical element comprises an anti-reflection coating at the surface facing the incident laser pulses. This may reduce optical losses originating in undesired reflections off the front surface of the nonlinear optical element.

In some exemplary embodiments the nonlinear optical element is arranged in a Brewster angle with respect to the direction of incidence of the laser pulses at a central wavelength of the laser pulses. The nonlinear optical element may be formed of a birefringent crystal cut at an angle, such that a k-vector of the incident laser pulses is parallel to the optical axis of the birefringent crystal. Therefore, the nonlinear optical element may comprise or consist of a crystal cut in a specific angle suitable for fulfilling both requirements.

In some exemplary embodiments the nonlinear optical element comprises or consists of TiO₂. A nonlinear optical element comprising or consisting of TiO₂ offers a high nonlinear refractive index n₂ of about 10⁻¹⁴ cm²/W (for rutile crystal structure) and a suitable transparency for laser pulses in the mid-infrared spectral range. In particular, the nonlinear optical element may therefore comprise or consist of rutile. In addition, rutile TiO₂ features a dispersion zero-crossing in the mid-infrared region being beneficial for supercontinuum-like octave-spanning spectral broadening in the 2-3 μm spectral wavelength region and optionally in the 1-4 μm spectral wavelength region. This may provide advantageous properties for spectral broadening of laser pulses emitted by a Cr-doped II-VI laser oscillator system having a central wavelength in the range from about 1.8 μm to 2.6 μm towards shorter wavelengths, i.e. in a spectral range below the fundamental wavelength spectrum of the laser pulses emitted by the laser oscillator system. For instance, the TiO₂ and in particular rutile based nonlinear optical element may be used for spectrally broaden the laser pulses to a wavelength down to about 1.2 μm (30 dB attenuation with respect to maximum of spectral power distribution). In addition, the TiO₂ and in particular rutile based nonlinear optical element may provide spectral broadening towards longer wavelengths further into the MIR spectral range.

In some exemplary embodiments the laser system further comprises a second nonlinear optical element for spectral broadening in the mid-infrared spectral range. The second nonlinear optical element optionally comprises or consists of ZnGeP₂ (also referred to as ZGP). The laser system may be adapted such that the laser pulses propagating through the second nonlinear optical element experience nonlinear frequency conversion. According to some exemplary embodiments the nonlinear frequency conversion may include intra-pulse difference frequency generation. Using a second nonlinear optical element for spectral broadening in the MIR spectral range allows optimizing the spectral broadening towards shorter wavelengths separately from optimizing the spectral broadening towards longer wavelengths. This may provide an additional degree of freedom regarding spectral broadening. The nonlinear optical element and the second nonlinear optical element may be arranged in a cascaded manner such that the laser pulses propagate through the nonlinear optical element prior to propagating through the second nonlinear optical element. However, the order of arranging the nonlinear optical elements may be reversed. In some exemplary embodiments, the laser pulses are compressed after propagating through the nonlinear optical element and prior to propagating through the second nonlinear optical element. Alternatively, or additionally the pulses may be compressed after propagating through the second nonlinear optical element. For instance, the laser system may comprise one or more laser pulse compression elements, such as diffraction gratings and/or prisms and/or grisms and/or chirped mirrors. In some exemplary embodiments, the nonlinear optical element may be formed of TiO₂, in particular rutile, and the second nonlinear optical element may be formed of ZGP. Accordingly, in some exemplary embodiments the method for generating light pulses having spectral components at a wavelength of at least 2 μm further comprises focusing the laser pulses onto a second nonlinear optical element comprising or consisting of ZnGeP₂, wherein the laser pulses propagating through the second nonlinear optical element experience nonlinear frequency conversion. The method may apply a laser oscillator system according to one of the presented exemplary embodiments.

In some exemplary embodiments, the laser system may be used for generating supercontinuum light pulses having covering a spectral range at least from 1.5 μm to 3.5 μm and having a pulse duration of 15 fs FWHM or less.

An exemplary embodiment relates to the use of rutile TiO₂ for nonlinear spectral broadening. In some exemplary embodiments, the use may comprise irradiating the rutile with laser pulses having a peak power of at least 0.75 MW and spectral components at a wavelength of at least 2 μm. This allows providing few-cycle laser pulses in the MIR spectral range based on laser pulses emitted from a laser oscillator system without the need of an external amplification.

In some exemplary embodiments of the use of rutile TiO₂ for nonlinear optical applications may comprise or consist of multiple-wave-mixing applications. Moreover, in some exemplary embodiments the use of rutile comprises using a nonlinear optical element made of rutile for nonlinear optical applications.

In some exemplary embodiments TiO₂ is used for spectral broadening of the laser pulses emitted by the Cr-doped II-VI laser oscillator system in particular to shorter wavelengths. Conventionally, TiO₂ has been used for spectral broadening and supercontinuum generation only in waveguides and in spectral regions being different from the MIR (see for instance C. C. Evans et al., “Spectral broadening in anatase titanium dioxide waveguides at telecommunication and near-visible wavelengths,” Opt. Express 21, 18582-18591 (2013) and K. Hammani et al., “Octave Spanning Supercontinuum in Titanium Dioxide Waveguides,” Applied Sciences 8, 543 (2018)).

So far, TiO₂ and in particular rutile has not been used for spectral broadening of pulses emitted by a Cr-doped II-VI laser oscillator. One reason may be that for obtaining strong spectral broadening exceeding one optical octave with a nonlinear medium that is thin, especially for the 1-MW-level of peak power of a femtosecond Cr-doped II-VI oscillator, the medium needs to have an uncommonly large nonlinear refractive index n₂. However, a large value of n₂ is usually accompanied with a small bandgap, leading to strong multi-photon absorption (MPA) for the small spot sizes of the laser beam at the nonlinear optical element. MPA leads to a significant reduction of the broadening capability and in extreme cases even to irreversible degradation of the crystal. In addition, the dispersion of rutile TiO₂ features a zero-crossing in the corresponding spectral region of a Cr-doped II-VI oscillator. Therefore, self-compression and in return self-focusing may improve the spectral broadening even further. However, the inventors found that TiO₂ and in particular rutile has suitable properties for a thin nonlinear optical element for spectral broadening of laser pulses in the spectral range around 2 μm wavelength. In this respect TiO₂ is a rather unusual material featuring both a large value of n₂ of about 10⁻¹⁴ cm²/W and a large bandgap of about 3.2 eV rendering it a suitable material for spectral broadening in a spectral range around 2 μm wavelength with minimum MPA.

Moreover, using rutile TiO₂ for nonlinear spectral broadening, in particular as a nonlinear optical element having a thickness of 1 mm or less, allows achieving substantial spectral broadening of femtosecond pulses in the MIR spectral range. Moreover, it provides the benefit that the beam may maintain high spatial and/or temporal quality, which are beneficial for the further use of the spectrally broadened laser pulses and in particular their focusability.

Using bulk rutile TiO₂ as a nonlinear optical element provides the advantage that it is insensitive against minute fluctuations in the pointing of the incident beam, which accordingly will not give rise to significant fluctuations of transmissivity and the stability of spectral broadening, as often observed in optical waveguides based on spatial confinement.

In another aspect a laser system is provided, wherein the laser system comprises a laser oscillator system being adapted to emit laser pulses having a peak power of at least 0.75 MW and emitting laser radiation at a central wavelength in the range from 1 μm to 4 μm and optionally in the range from 2 μm to 3 μm. The laser system further comprises a nonlinear optical element having a thickness of 1 mm or less. The laser system is adapted to irradiate the nonlinear optical element with the laser pulses emitted by the laser oscillator system to spectrally broaden the laser pulses such that the spectrally broadened laser pulses span at least half an optical octave. The nonlinear optical element may comprise or consists of TiO₂ and in particular may comprise or consist of rutile TiO₂. The laser oscillator system may be adapted as a Thulium laser, i.e. having a gain medium based on Thulium.

The nonlinear optical element may have a thickness being essentially ten times larger than a one-sided Rayleigh length of the laser pulses focused into the nonlinear optical element or less. “Essentially” in this context means that a deviation between the thickness and a multiple of ten of the one-sided Rayleigh length is less than 10% of the thickness of the nonlinear element.

It is understood by a person skilled in the art that the above-described features and the features in the following description and figures are not only disclosed in the explicitly disclosed exemplary embodiments and combinations thereof, but that also other technically feasible combinations as well as the isolated features are comprised by the disclosure. In the following, several exemplary embodiments and specific examples are described with reference to the figures for illustration without limiting the disclosure to the described exemplary embodiments.

### BRIEF DESCRIPTION OF THE DRAWINGS

The disclosure will now be described with reference to the drawings wherein:

FIG. 1 schematically illustrates a laser oscillator system according to a first exemplary embodiment;

FIG. 2 schematically depicts a laser oscillator system according to a second exemplary embodiment;

FIG. 3 schematically illustrates the use of nonlinear optical element according to an exemplary embodiment for spectral broadening of laser;

FIG. 4 shows in diagram the normalized spectral intensity over the wavelength before and after spectral broadening;

FIG. 5 shows a laser system according to an exemplary embodiment;

FIG. 6 shows a laser system according to another exemplary embodiment; and

FIG. 7 exemplarily depicts a spectral power distribution of generated MIR radiation.

### DESCRIPTION OF EXEMPLARY EMBODIMENTS

In the drawings the same reference signs are used for corresponding or similar features in different drawings.

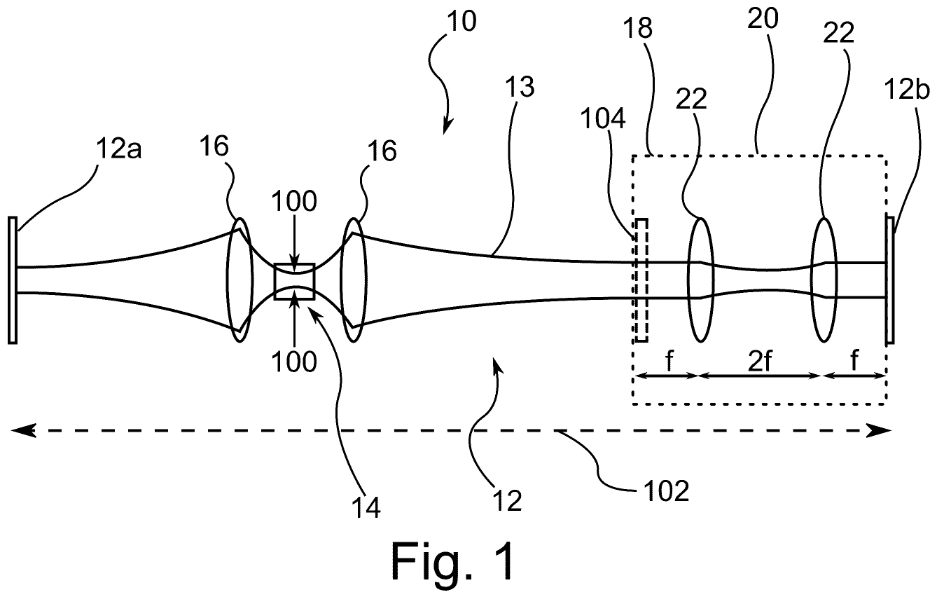

FIG. 1 schematically illustrates a laser oscillator system 10 according to a first exemplary embodiment. The laser oscillator system 10 comprises a resonator cavity 12 for confining an intra-cavity laser beam 13. Both ends of the resonator cavity 12 a respective cavity mirror 12a, 12b is arranged. The cavity mirrors 12a, 12b may also be referred to as end minors. According to an exemplary embodiment, one of the cavity mirrors 12a, 12b may comprise the functionality of an out-coupler for coupling a part of the intra-cavity laser beam 13 out of the resonator cavity 12. For instance, the cavity mirror 12a forming the out-coupler may be partly transparent for transmitting a small fraction of the intra-cavity laser beam 13.

Moreover, the laser oscillator system 10 comprises a Cr-doped II-VI gain medium 14 serving as a laser active medium. According to the presented exemplary embodiment the gain medium 14 may be a Cr:ZnSe or a Cr:ZnS gain medium which is well suited of amplifying optical radiation in a spectral range from about 1.8 μm to 3.0 μm. The gain medium may be directly diode-pumped by suitable laser diodes (not shown). For shaping the intra-cavity laser beam 13 to exhibit a suitable spot size 100, i.e. a suitable beam waist, at and within the gain medium 14, two optical elements 16 are provided for focusing and collimating the intra-cavity laser beam 13 accordingly. The optical elements may be provided as optical lenses.

According to the presented exemplary embodiment the gain medium 14 not only serves as the laser active medium for amplifying the intra-cavity laser beam 13 but also serves as Kerr medium for achieving Ken-lens mode-locking for the laser oscillator system 10. In other words, the gain medium 14 combines gain medium and Ken-medium in one and the same element.

The laser oscillator system 10 additionally comprises an imaging unit 18 for decoupling the spot size 100 of the intra-cavity laser beam 13 from an intra-cavity length 102 of the resonator cavity 12 indicated as a dashed double-arrow in FIG. 1. According to the presented exemplary embodiment the imaging unit 18 is formed by a 4f-telescope 20 in the vicinity of the cavity mirrors 12b. The 4f-telescope comprises two optical lenses 22 each having a focal length f, wherein the two optical lenses 22 are arranged in a distance of twice the focal length f, i.e. in a distance of 2f, from each other. Moreover, one of the optical lenses 22 is placed in a distance corresponding to the focal length f from the cavity mirror 12b. The imaging unit 18, thus is configured to image the intra-cavity laser beam 13 from an image plane 104 to the cavity mirror 12b placed adjacent to the imaging unit 18. Hence, the optical configuration of the resonator cavity 12 including the imaging unit virtually provide an image of the cavity mirror 12b in the image plane 104. The resonator mode of the intra-cavity light beam 13 in the part of the resonator cavity 12 extending from the left cavity mirror 12a to the image plane 104, thus, defines the resonator mode in the same manner as the resonator mode would be if the right cavity mirror 12b was placed in the image plane 104. The extension of the intra-cavity length 102 of the resonator cavity 12 provided by the imaging unit 18, thus, does not alter the resonator mode and in particular does not influence the spot size 100 of the intra-cavity laser beam 13 at the gain medium. This is in contrast to a mere extension of the intra-cavity length 102 of the resonator cavity 12 without an imaging unit 18, in which case due to the focusing of the intra-cavity laser beam 13 by the cavity mirrors 12a and 12b, the beam waist 100 would change with increased intra-cavity length 102.

Due to the extended length of the resonator cavity 12 by using the imaging unit 18 the repetition rate of the laser oscillator system 10 is reduced compared to the case of placing the cavity mirror 12b in the imaging plane 104. By this, repetition rates of 50 MHz or less may be realized. In some exemplary embodiments repetition rates of 40 MHz or less or even 30 MHz or less may be realized. The reduced repetition rates allow achieving higher pulse energies and, hence, a higher peak power of the emitted laser pulses, since the average laser output power (which essentially remains unchanged) is concentrated into a reduced number of pulses. In particular, the presented exemplary embodiment is capable of realizing a repetition rate of 25 MHz corresponding to an intra-cavity length of 6.0 meters. Accordingly, the laser oscillator system may be capable of providing femtosecond laser pulses having a peak power of 1 MW or more.

According to an exemplary embodiment, the laser oscillator system 10 has a tunable intra-cavity resonator length. For instance, the position of the cavity minor 12b and optionally of the imaging unit 18 may be moved in order to shorten and/or extend the intra-cavity length 102 of the resonator cavity 12. For instance, the length of the resonator cavity may be tunable in a continuous manner and/or may be stepwise tunable. According to some exemplary embodiments, the intra-cavity length 102 of the resonator cavity 12 may be changed to some degree without requiring a change of the optical elements 22 of the imaging unit 18. According to some exemplary embodiments, a change of the intra-cavity length 102 of the resonator cavity 12 may require replacing at least one of the optical elements 22 by a different optical element having a different focal length.

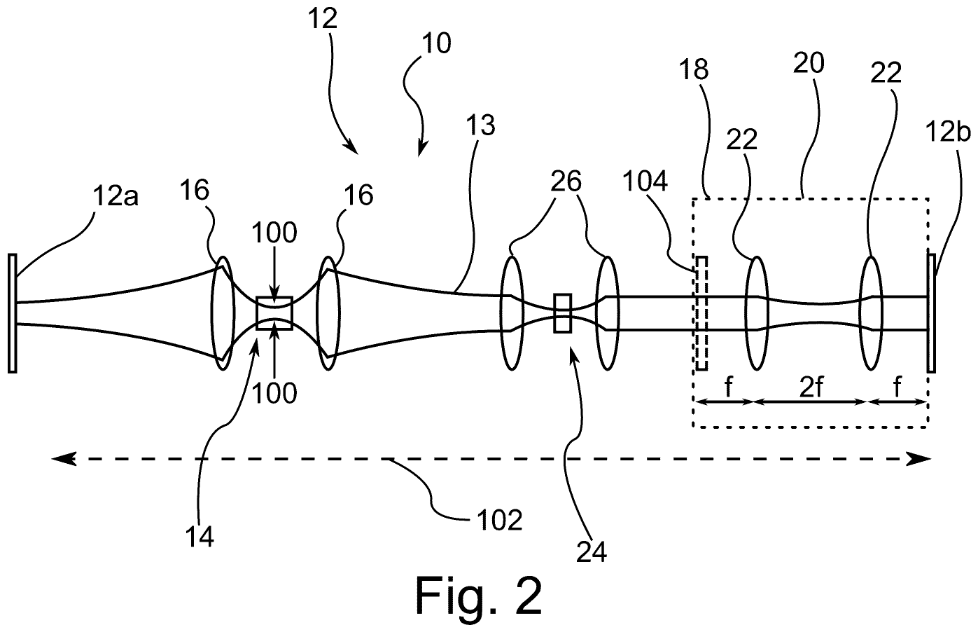

FIG. 2 schematically depicts a laser oscillator system 10 according to a second exemplary embodiment which corresponds to the laser oscillator system 10 according to the first exemplary embodiment in most aspects. However, the second exemplary embodiment differs from the first exemplary embodiment in the feature that it provides a Kerr medium 24 for Kerr-lens mode locking separate from the gain medium 14. In addition, the laser oscillator system 10 according to the second exemplary embodiment provides two further optical elements 26 for focusing and collimating the intra-cavity laser beam 13 onto the Kerr medium 24. Having these additional features, the laser oscillator system 10 according to the second exemplary embodiment allows adjusting the spot size of the intra-cavity laser beam 13 at the gain medium and the spot size at the Kerr medium 24 independently of each other. Hence, the gain may be controlled by adjusting the spot size of the intra-cavity laser beam 13 at the gain medium choosing and adjusting the focal lengths and the positioning of the optical elements 16 surrounding the gain medium 14 and the Ken-lens mode-locking may be independently controlled by adjusting the Kerr-effect by choosing and adjusting the focal lengths and the positioning of the optical elements 26 surrounding the Kerr medium 24. This provides an additional degree of freedom for controlling the parameters of the laser oscillator system 10.

This decoupling enables further scaling of the peak power of the laser pulses emitted by the laser oscillator system 10, since the spot size 100 at the gain medium 14 and optionally an overlap between a pump beam and the intra-cavity laser beam 13 for soft-aperture mode-locking can be optimized for maximum laser gain independently of the optimization of the Kerr-nonlinearity for optimal initiation and maintenance of mode-locked operation, which may be optimized via a thickness and/or position and/or focus spot size in the separate Kerr medium 24.

The resulting peak-power achievable with the laser oscillator system 10, when reaching or exceeding 1 MW, is high enough to efficiently drive nonlinear processes such as spectral broadening via self-phase-modulation (SPM) in suitable nonlinear media. Apart from wider spectral reach, the spectrally broadened pulse may be compressed in the temporal domain to shorter durations as well.

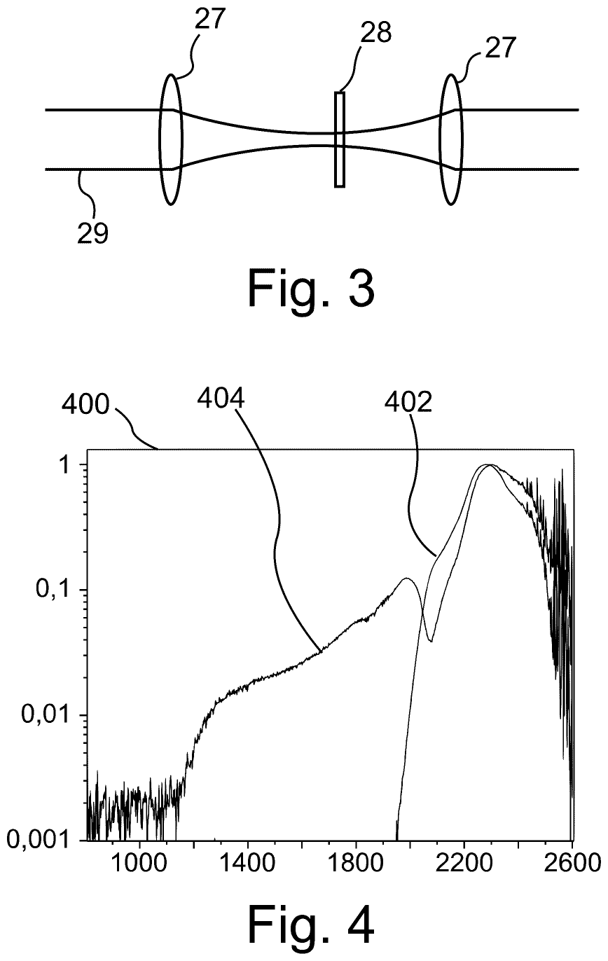

FIG. 3 schematically illustrates the use of a nonlinear optical element 28 according to an exemplary embodiment for spectral broadening of laser pulses incident as a laser beam 29, which is focused and collimated by respective optical elements 27. The nonlinear optical element 28 is made of bulk TiO₂ having a rutile crystal structure and is provided as a homogeneous piece of material free from any macroscopic structure that would impose waveguiding to the incident laser beam 29. The nonlinear optical element has a thickness in the propagation direction of the laser beam which is 1 mm or less. This allows maintaining the laser beam 29 with a high beam quality factor M² which ensures a high degree of focusability after the spectral broadening and, hence, a good usability of the spectrally broadened laser pulses for applications requiring strong focusing. Due to the limited thickness of the nonlinear optical element a possible degradation of the beam profile during the spectral broadening is limited, which results in the high beam quality factor. For achieving a considerable amount of spectral broadening in the thin nonlinear optical element it may be advantageous to place the nonlinear optical element 28 closer to the focus of the laser beam 29 as compared to a typical position of a thicker nonlinear optical element having a thickness of several millimeters. The small spot size of the laser beam 29 within the thin nonlinear optical element 28 leads to a strong Kerr-lensing effects resulting in a remixing of the wavelength components of the laser beam 29 and, thus, increases the homogeneity of the spectral distribution over the beam profile. This homogenization of the spectral components reduces the degradation of the beam profile as the spectrum broadens.

Thus, by using a thin nonlinear optical 28 element having a thickness of 1 mm or less for spectral broadening, the transmitted laser beam retains high spatial and temporal qualities advantageous for further use, such as a subsequent generation of mid-infrared radiation.

FIG. 4 shows in diagram 400 the normalized spectral intensity (vertical axis, logarithmic scale) over the wavelength (in nanometers). The graph 402 represents the normalized spectral intensity of the laser pulses emitted by a Cr-doped II-VI laser oscillator system according to an exemplary embodiment prior to any additional spectral broadening. As can be seen, the spectral intensity peaks at a wavelength around 2.2 μm and extends on the short wavelength side to about 2.05 μm before decreasing in a steep manner The cut-off wavelength being attenuated by about 30 dB compared to the maximum, i.e. having a normalized intensity of 10⁻³, is reached at a wavelength of about 1.95 μm. On the longer wavelength side the spectrum extends until about 2.45 m. Accordingly, the spectrum of the laser pulses as emitted by the laser oscillator system 10 according to an exemplary embodiment extend from about 1.95 μm to about 2.45 μm. After spectral broadening of the laser pulses in a device detailed with reference to FIG. 3, the spectrum significantly gains additional spectral components, as presented in graph 404. Spectral broadening of the laser pulses was achieved by focusing the laser pulses into a nonlinear optical element 28 formed of a bulk rutile TiO₂ plate having a thickness of 0.5 mm. Graph 404 reveals that a significant amount of spectral broadening occurred, in particular on the short wavelength side, resulting in a spectral intensity distribution extending down to a wavelength of about 1.2 μm before vanishing in the noise. Likewise, on the longer wavelength side the spectral intensity increased in the wavelength range from about 2.2 μm to about 2.4 μm. Thus, the spectral broadening resulted in a significant gain of spectral components on the short as well as the long wavelength side of the original spectrum of the laser pulses emitted by the laser oscillator system.

In some exemplary embodiments, laser pulses may be used, with or without spectral broadening in a nonlinear optical element 28 as for instance illustrated in FIG. 3, for the generation of mid-infrared radiation extending to even longer wavelengths in the MIR spectral range. The generation of the MIR radiation may be carried out via nonlinear frequency conversion using the laser pulses emitted by the laser oscillator system without additional spectral broadening or using the laser pulses provided by the laser system including spectral broadening as illustrated in FIG. 3. Both techniques are suitable for the generation of MIR radiation without the need of further amplification of the laser pulses in an amplifier stage besides the laser oscillator system.

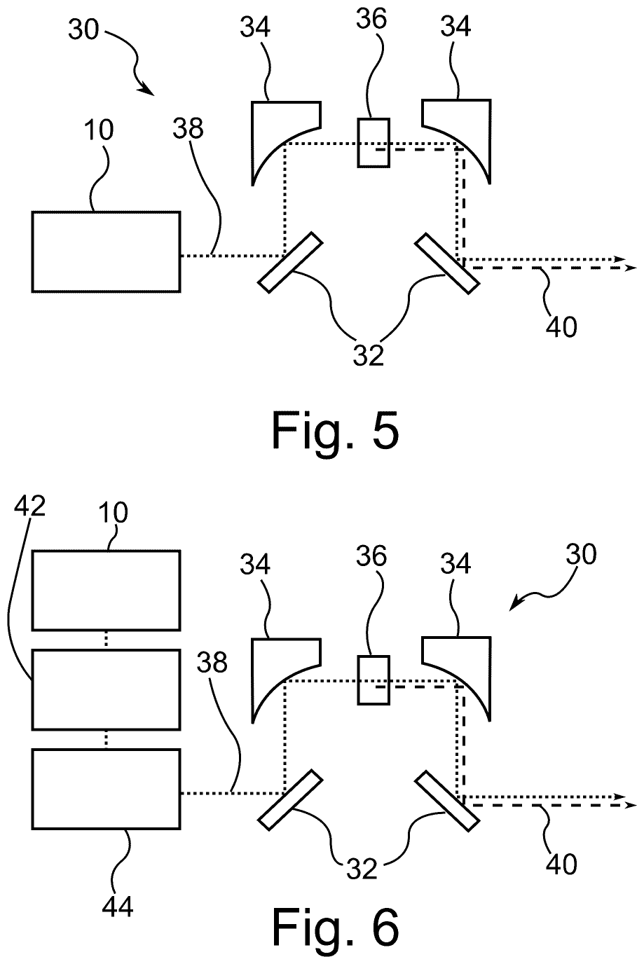

In an exemplary embodiment of a laser system 30 illustrated on FIG. 5, the laser pulses emitted by a Cr-doped II-VI laser oscillator system 10 having a peak power of at least 0.75 MW are directly focused onto a (second) nonlinear optical element for nonlinear frequency conversion and MIR generation. In order to reduce optical dispersion and a resulting deterioration of the pulse shape of the emitted laser pulses, the laser system 30 for nonlinear frequency conversion shown in FIG. 5 comprises reflective optical elements, which comprise two steering mirrors 32 and two off-axis parabolic mirrors 34 for focusing the laser pulses onto the nonlinear optical element for nonlinear frequency conversion and generation of MIR radiation 36 and collimating the laser pulses (also referred to as second nonlinear optical element 36). The dotted line 38 indicates the optical path of the laser pulses. The dashed line 40 indicates the optical path of the MIR radiation generated by the laser pulses in the second nonlinear optical medium by nonlinear frequency conversion and in particular by intra-pulse difference frequency generation. As indicated, the propagation directions of the laser pulses and the generated MIR radiation are identical.

FIG. 6 depicts a laser system 30 including nonlinear frequency conversion according to another exemplary embodiment, which in most aspects corresponds to the exemplary embodiment of the device 30 presented in FIG. 5. However, the device 30 according to this exemplary embodiment differs from the device 30 presented in FIG. 5 in the feature that the laser pulses used for the generation of MIR radiation are subject to prior spectral broadening in a nonlinear optical element (as exemplarily illustrated in FIG. 3) and pulse compression. For this purpose, the laser pulses emitted by the Cr-doped II-VI laser oscillator system 10 are applied to respective devices for nonlinear spectral broadening 42 and for temporal pulse compression 44 prior to focusing the laser pulses onto the second nonlinear optical element 36 for nonlinear frequency generation and generation of MIR radiation.

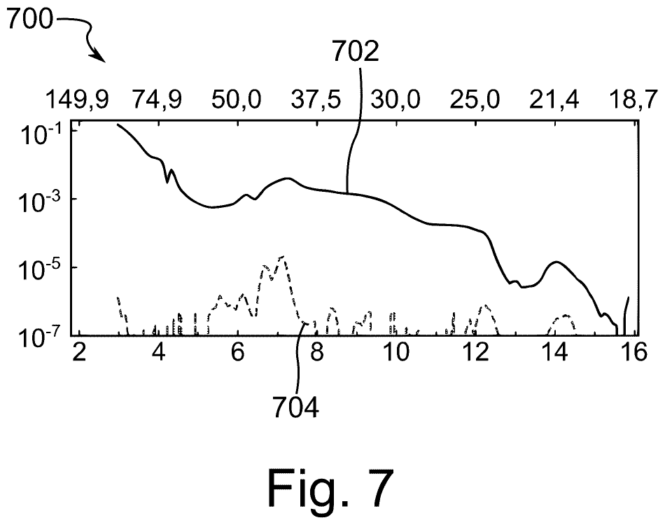

FIG. 7 exemplarily depicts in diagram 700 a spectral power distribution of MIR radiation generated by a laser system 30 presented with reference to FIG. 5, wherein the nonlinear frequency conversion and MIR radiation generation was driven by laser pulses emitted by a Cr:ZnS laser oscillator system having a peak power of 1 MW. No spectral broadening and pulse compression were applied prior to the MIR radiation generation.

Diagram 700 shows the spectral power (in mW/nm) at the vertical axis, the wavelength (in micrometers) at the lower horizontal axis and the frequency (in THz) at the upper horizontal axis. The solid line of graph 702 indicates the spectral power obtained by the nonlinear frequency conversion driven by the laser pulses, which provide an estimated peak intensity of 87 GW/cm² in the nonlinear optical medium for nonlinear frequency conversion arranged in the focus of the laser pulses. Graph 702 shows that the spectral power distribution ranges to about 15 μm at a spectral power in a range from 10⁻⁴ mW/nm to about 10⁻⁶ mW/nm. The significant amount of MIR radiation generated in the process becomes even more apparent when compared to the spectral power of (essentially not existing) MIR radiation (graph 704) generated with a focal peak intensity of only 13 GW/cm², a peak power which may be reachable by conventional Cr-doped II-VI laser oscillator systems. As graph 704 shows, basically no spectral power is generated in the MIR with an intensity of 13 GW/cm², since graph 704 essentially corresponds to detection noise. Thus, diagram 700 demonstrates that a Cr-doped II-VI laser oscillator system according an exemplary embodiment providing laser pulses having a peak power of at least 0.75 MW or even at least 1 MW are well suited for the generation MIR radiation, even without prior spectral broadening and pulse compression, while conventional Cr-doped II-VI laser oscillator systems do not provide laser pulses having a sufficient peak power to generate MIR radiation in the absence for further external amplification.

The foregoing description of the exemplary embodiments of the disclosure illustrates and describes the present invention. Additionally, the disclosure shows and describes only the exemplary embodiments but, as mentioned above, it is to be understood that the disclosure is capable of use in various other combinations, modifications, and environments and is capable of changes or modifications within the scope of the concept as expressed herein, commensurate with the above teachings and/or the skill or knowledge of the relevant art.

The term comprising (and its grammatical variations) as used herein is used in the inclusive sense of having or including and not in the exclusive sense of consisting only of. The terms a and the as used herein are understood to encompass the plural as well as the singular.

All publications, patents and patent applications cited in this specification are herein incorporated by reference, and for any and all purposes, as if each individual publication, patent or patent application were specifically and individually indicated to be incorporated by reference. In the case of inconsistencies, the present disclosure will prevail.

### List of Reference Signs

10 laser oscillator system
12 resonator cavity
12a, 12b cavity mirror/end minor
13 intra-cavity laser beam
14 gain medium
16 optical elements
18 imaging unit
20 4f-telescope
22 optical elements of imaging unit
24 Kerr medium
26 optical element
27 optical element
28 nonlinear optical element (for spectral broadening)
29 laser beam
30 laser system
32 steering mirror
34 parabolic mirror
36 (second) nonlinear optical element (for nonlinear frequency conversion)
38 optical path of laser pulses
40 optical path of generated MIR radiation
42 device for spectral broadening
44 device for temporal pulse compression
ƒ focal length of optical element 22
100 spot size/beam waist at gain medium
102 intra-cavity length of resonator cavity
104 image plane of 4f-telescope
400 diagram illustrating a spectral intensity before and after spectral broadening
402 normalized intensity of emitted laser pulses
404 normalized intensity after spectral broadening
700 diagram illustrating the spectral power after MIR generation
702 spectral power of MIR radiation generated at 87 GW/cm²
704 spectral power of MIR radiation generated at 13 GW/cm²

1. A laser oscillator system comprising:
a resonator cavity configured to confine an intra-cavity laser beam;
a Cr-doped II-VI gain medium arranged within the resonator cavity; and
an imaging unit forming part of the resonator cavity,
wherein the imaging unit is configured to decouple a spot size of the intra-cavity laser beam at the gain medium from an intra-cavity length of the resonator cavity, and
wherein the resonator cavity and the imaging unit are configured such that the laser oscillator system emits laser pulses at a repetition rate of 50 MHz or less.

2. The laser oscillator system according to claim 1, wherein the imaging unit is configured to provide a tunable intra-cavity length.

3. The laser oscillator system according to claim 2, wherein the spot size of the intra-cavity laser beam at the gain medium is adjustable.

4. The laser oscillator system according to claim 1, wherein the imaging unit comprises one or more telescopes for imaging the intra-cavity laser beam, and wherein the one or more telescopes optionally contain one or more 4 f-telescopes.

5. The laser oscillator system according to claim 4, wherein an end minor of the resonator cavity is arranged in one of the imaging planes of the one or more telescopes.

6. The laser oscillator system according to claim 1, wherein the resonator cavity and optionally the imaging unit comprise one or more multipass-cells, and wherein the one or more multipass-cells optionally comprise one or more Herriott-type cells.

7. The laser oscillator system according to claim 1, wherein the Cr-doped II-VI gain medium comprises or consists of ZnS and/or ZnSe, and wherein the ZnS and/or the ZnSe optionally are polycrystalline.

8. The laser oscillator system according to claim 1, wherein the gain medium is oriented at a Brewster angle at the central wavelength of the intra-cavity laser beam or at a normal incidence angle of the intra-cavity laser beam.

9. The laser oscillator system according to claim 1, wherein the resonator cavity and the imaging unit are configured such that the laser oscillator system emits laser pulses at a repetition rate of 40 MHz or less.

10. The laser oscillator system according to claim 1, wherein the laser oscillator system is configured to emit the laser pulses having a pulse duration of 30 fs FWHM or less and/or a peak power of at least 0.75 MW and optionally of at least 1 MW.

11. The laser oscillator system according to claim 1, wherein the emitted laser pulses cover a spectral range from at least 2.0 μm to 2.8 μm.

12. The laser oscillator system according to claim 1, wherein the laser oscillator system is configured as a Kerr-lens mode-locked laser oscillator system.

13. The laser oscillator system according to claim 12, wherein the gain medium is configured to provide a functionality of a Kerr medium for Kerr-lens mode locking.

14. The laser oscillator system according to claim 12, further comprising a Kerr medium, wherein the Kerr medium is provided separately from the gain medium.

15. The laser oscillator system according to claim 1, wherein the Cr-doped II-VI gain medium is directly diode-pumped.

16. A laser system, comprising:
the laser oscillator system according to claim 1, wherein the laser oscillator system is configured to emit laser pulses having a peak power of at least 0.75 MW;
a nonlinear optical element having a thickness of 1 mm or less;
wherein the laser system is configured to irradiate the nonlinear optical element with the laser pulses emitted by the laser oscillator system to spectrally broaden the laser pulses such that the spectrally broadened laser pulses span at least half an optical octave.

17. The laser system according to claim 16, wherein the laser system is configured to focus the laser pulses onto the nonlinear optical element.

18. The laser system according to claim 16, wherein the laser system is configured such that the spectrum of the laser pulses supports a pulse duration of 15 fs or less after propagating through the nonlinear optical element.

19. The laser system according to claim 16, wherein the nonlinear optical element comprises an anti-reflection coating at the surface facing the incident laser pulses.

20. The laser system according to claim 16, wherein the nonlinear optical element is arranged in a Brewster angle with respect to a direction of incidence of the laser pulses at a central wavelength of the laser pulses, and wherein the nonlinear optical element is formed of a birefringent crystal cut at an angle, such that a k-vector of the incident laser pulses is parallel to an optical axis of the birefringent crystal.

21. The laser system according to claim 16, wherein the nonlinear optical element comprises or consists of TiO₂.

22. The laser system according to claim 21, wherein the nonlinear optical element comprises or consists of rutile TiO₂.

23. The laser system according to claim 16, further comprising a second nonlinear optical element for spectral broadening in the mid-infrared spectral range, wherein the second nonlinear optical element optionally comprises or consists of ZnGeP₂, and wherein the laser system is configured such that the laser pulses propagating through the second nonlinear optical element experience nonlinear frequency conversion.

24. A method for generating light pulses having spectral components at a wavelength of at least 2 μm, the method comprising:
providing laser pulses emitted by a laser oscillator having a pulse duration of 30 fs FWHM or less, a peak power of at least 0.75 MW, and a central wavelength of 1.8 μm or longer; and
focusing the laser pulses onto a nonlinear optical element having a thickness of 1 mm or less and a nonlinear refractive index n₂ of at least 5·10⁻¹⁹ m²/W at a wavelength of 2 μm.

25. The method according to claim 24, wherein the nonlinear optical element is a nonlinear optical element for nonlinear frequency conversion comprising or consisting of ZnGeP₂.

26. The method according to claim 24, wherein the nonlinear optical element comprises or consists of TiO₂ and optionally of rutile TiO₂.

27. The method according to claim 26, wherein the nonlinear optical element has a thickness being not more than ten times larger than a one-sided Rayleigh length of the laser pulses focused into the nonlinear optical element.

28. The method according to claim 26, further comprising focusing the laser pulses onto a second nonlinear optical element comprising or consisting of ZnGeP₂, wherein the laser pulses propagating through the second nonlinear optical element experience nonlinear frequency conversion.

29. The method according to claim 24, wherein the laser oscillator comprises:
a resonator cavity configured to confine an intra-cavity laser beam;
a Cr-doped II-VI gain medium arranged within the resonator cavity; and
an imaging unit forming part of the resonator cavity,
wherein the imaging unit is configured to decouple a spot size of the intra-cavity laser beam at the gain medium from an intra-cavity length of the resonator cavity, and wherein the resonator cavity and the imaging unit are configured such that the laser oscillator system emits laser pulses at a repetition rate of 50 MHz or less.

30. A method for generating laser pulses having a peak power of at least 0.75 MW, the method comprising:
utilizing the a laser oscillator system according to claim 1 at a repetition rate of 50 MHz or less.

31. A method for generating supercontinuum light pulses, the method comprising:
utilizing the a laser system according to claim 16, wherein the supercontinuum light pulses cover a spectral range at least from 1.5 μm to 3.5 μm and have a pulse duration of 15 fs FWHM or less.

32. A method for nonlinear spectral broadening of laser pulses, the method comprising:
providing bulk rutile TiO₂, wherein the spectrally broadened laser pulses have spectral components at a wavelength of at least 1 μm.

33. The method according to claim 32, wherein the spectral components of the laser pulses have a wavelength in a range from 1 μm to 4 μm.

34. The method according to claim 32, wherein the spectral components of the laser pulses have a wavelength of at least 2 μm.

35. The method according to claim 32, comprising irradiating the rutile with laser pulses having a peak power of at least 0.75 MW.

36. The method according to claim 32, wherein the laser pulses have a wavelength in a range from 2 μm to 3 μm.

37. The method according to claim 32, comprising at least one nonlinear optical application comprising or consisting of a multiple-wave-mixing application.

38. The method according to claim 32, wherein the use of rutile comprises using a nonlinear optical element comprising or consisting of rutile for the nonlinear optical applications.

39. The method according to claim 38, wherein the nonlinear optical element has a thickness of 1 mm or less.

40. The method according to claim 38, wherein the nonlinear optical element has a thickness being not more than ten times larger than a one-sided Rayleigh length of the laser pulses focused into the nonlinear optical element.

41. The method according to claim 38, wherein the nonlinear optical element has a thickness of 100 μm or more.
